(19) United States
(12) Patent Application Publication
(10) Pub. No.: US 2005/0202655 A1
(43) Pub. Date: Sep. 15, 2005

(54) Method for manufacturing semiconductor device

(75) Inventor: Hiroki Sakamoto, Takatsuki-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/072,265

(22) Filed: Mar. 7, 2005

(30) Foreign Application Priority Data
Mar. 9, 2004 (JP) 2004-065547

(51) Int. Cl. H01L 21/3205; H01L 21/36

(52) U.S. Cl. 438/491; 438/592

(57) ABSTRACT

By improving a surface morphology of the polysilicon film and controlling crystallization thereof, an increase in resistance of a silicide film can be prevented and a silicide film having a low resistance and high reliability can be formed. A method for manufacturing a semiconductor device comprises the steps of forming a gate insulation film on a silicon substrate to deposit a polysilicon film on the gate insulation film, and patterning the polysilicon film to form a gate electrode on the gate insulation film, wherein the gate electrode is silicidized to form a silicide, and a resistance of the silicide film is stabilized by reducing a crystal size in the polysilicon film and reducing a degree of variance of the number of the crystals contained in the polysilicon film. Because of this, the surface morphology of the polysilicon film can be improved, thereby making it possible to stabilize the silicide resistance. In addition, by controlling a grain size of the polysilicon, a resistance increase caused by separated portions generated in the silicide film can be prevented.

### BACKGROUND OF THE INVENTION

1. Field of the Invention

The present invention relates to a method for manufacturing a semiconductor device, and particularly to a method for manufacturing a semiconductor device provided with a gate insulation film for elements having a reduced film thickness, and a semiconductor device provided with a silicide layer obtained by silicidizing a metal.

2. Description of the Prior Art

Conventionally, in an LSI (Large Scale Integrated circuit), in order to increase integration density of a semiconductor chip, miniaturization and a reduction in operation voltage of a MOSFET (Metal Oxide Semiconductor Field Effect Transistor) being an element composing the LSI, have been promoted. Meanwhile, an operating speed of the component is increased by highly integrating the components, so that as a method of achieving a low resistance of a gate electrode or a diffusion layer, the so-called salicide process is well known, which uses a metal film such as cobalt (Co), titanium (Ti), tungsten (W) or the like to form a silicide film in the gate electrode and the diffusion layer using a self-alignment (refer to, for example Japanese Laid-Open Patent Application No. Hei 02-45923). Hereinafter, a method for manufacturing a semiconductor device using a conventional salicide process will be explained.

FIGS. 6A through 6D are sectional views showing an example of a conventional process of manufacturing a semiconductor device.

First, at a process shown in FIG. 6A, after forming an insulation film for device isolation 101 of trench type surrounding an active region of a semiconductor substrate 100, a gate insulation film 102 composed of a silicon oxide/nitride film with a thickness of 1 nm to 3 nm is formed on the active region of the semiconductor substrate 100. Then, a polysilicon film 103 is deposited on the substrate using LPCVD (Low Pressure Chemical Vapor Deposition) at a film-forming temperature of 600° C. to 620° C., a film-forming pressure of 20 Pa and 50 Pa, and an SiH₄ flow-rate of 500 sccm to 1,000 sccm.

Next, at a process shown in FIG. 6B, the polysilicon film is patterned using lithography and dry etching to form a gate electrode 104 on the gate insulation film 102. Then, low-concentration impurity ions are implanted into the active region using the gate electrode 104 and the insulation film for device isolation 101 as a mask, and an LDD region is formed in a self-aligning manner to the gate electrode 104. Then, an oxide film is deposited on the substrate using a CVD method, and a sidewall 105 composed of the oxide film is formed on the side of the gate electrode 104 by etching-back the oxide film. Then, high-concentration impurity ions are implanted into the active region using the gate electrode 104, the sidewall 105, and the insulating film for device isolation 101 as a mask, and high-concentration source/drain regions 106 are formed therein in a self-aligning manner to the gate electrode 104.

Next, at a process shown in FIG. 6C, after depositing a cobalt film 107 on the substrate using a sputtering method, a titanium nitride film 108 is deposited on the cobalt film 107. Next, at a process shown in FIG. 6D, a first short time heat treatment (RTA, rapid thermal annealing) is applied to the semiconductor substrate 100 at a temperature of approximately 400° C. to 500° C. in a nitrogen gas atmosphere, and silicon (Si) and cobalt (Co) are reacted in exposed portions of the gate electrode 104 and the high-concentration source/drain regions 106 to form a first cobalt silicide film 109 having cobalt-rich formation. At this time, the cobalt film 107 on the sidewall 105 and on the insulation film, such as the isolation film for device isolation 101 or the like are not silicidized and the cobalt film 107 is left unreacted. Next, by selectively removing the titanium nitride film 108 and the cobalt film 107 that are left unreacted using a solution such as a mixture of sulfuric acid and oxygenated water, the first cobalt silicide film 109 composed of polycrystals is selectively left on the gate electrode 104 and the high-concentration source/drain regions 106.

Next, a second short time heat treatment (RTA) is applied to the semiconductor substrate 100 at a temperature of approximately 800° C. to 900° C. in a nitrogen gas atmosphere, so that the first cobalt silicide film 109 is transformed into a second cobalt silicide film (CoSi₂ film) which is structurally stable. As a result, a sheet resistance of the second cobalt silicide film is reduced to be lower than that of the first cobalt silicide film 109, thereby making it possible to achieve a reduction in resistance of the gate electrode 104 and the high-concentration source/drain regions 106.

However, in the conventional method for manufacturing the semiconductor devices described above, there have been problems that a crystal size of the polysilicon film 103 has been large and the silicide film has also been condensed due to an effect of the polysilicon film 103, resulting in a higher resistance of the silicide film. In particular, when the gate length is reduced to be 0.1 micrometer or less, the resistance of the silicide film affected by the polysilicon film 103 is significantly increased. One of the major factors to determine the resistance of the silicide film includes a size of silicon crystals, and even when the polysilicon film is composed of an aggregate of crystals having the same grain size, the numbers of crystals included in the polysilicon films are not the same when cutting the polysilicon films in a gate length direction as shown in FIGS. 7A and 7B. Moreover, the larger the crystal size and the shorter the gate length is, the larger the degree of variance in the number of crystals is.

### SUMMARY OF THE INVENTION

It is an object of the present invention to prevent an increase in resistance of the silicide film owing to a surface morphology improvement and a crystallization control of the polysilicon film, and thereby provide a method for manufacturing a semiconductor device having a silicide film with characteristics of a low resistance and high reliability.

In order to achieve the above object, according to a first aspect of the present invention, there is provided a method for manufacturing a semiconductor device, including the steps of forming a gate insulation film on a silicon substrate to deposit a polysilicon film on the gate insulation film, and patterning the polysilicon film to form a gate electrode on the gate insulation film, wherein the gate electrode is silicidized to form a silicide film, and by reducing a crystal size in the polysilicon film and reducing a degree of variance of the number of crystals contained in the polysilicon film, a resistance of the silicide film is stabilized.

According to this configuration, a silicide resistance can be stabilized by improving a surface morphology. When the crystal size of the polysilicon film is large, the silicide film is also condensed by an influence of the polysilicon film, so that a problem that the resistance of the silicide film is increased may arise, whereas a resistance increase caused by separated portions generated in the silicide film can be prevented by controlling a grain size of the polysilicon, thereby making it possible to make a semiconductor device having the silicide film with low resistance, even when the gate electrode and the source/drain regions are miniaturized.

According to a second aspect of the present invention, there is provided a method for manufacturing a semiconductor device, wherein, in the method of the semiconductor device according to the first invention, the step of depositing the polysilicon film sets a reaction pressure to be in a range of 1 Pa to 15 Pa.

According to this configuration, a partial pressure of SiH₄ is reduced, so that a size of silicon crystals is also reduced. As a result, a resistance of the silicide film with gate length of 0.1 micrometers or less can be stabilized.

According to a third aspect of the present invention, there is provided a method for manufacturing a semiconductor device, wherein, in the method of the semiconductor device according to the first aspect, the step of depositing the polysilicon film sets an SiH₄ partial pressure to be in a range of 1 Pa to 15 Pa.

According to this configuration, the partial pressure of SiH₄ is reduced, resulting in a small silicon crystal size. As a result, the resistance of the silicide film with gate length of 0.1 micrometers or less can be stabilized.

According to a fourth aspect of the present invention, there is provided a method for manufacturing a semiconductor device, wherein, in the method of the semiconductor device according to the third aspect, the SiH₄ partial pressure is reduced by diluting with N₂ gas.

According to this configuration, the partial pressure of SiH₄ is reduced, resulting in a small silicon crystal size. As a result, the resistance of the silicide film with gate length of 0.1 micrometers or less can be stabilized.

According to a fifth aspect of the present invention, there is provided a method for manufacturing a semiconductor device, wherein, in the method of the semiconductor device according to the third aspect, the SiH₄ partial pressure is reduced by diluting with H₂ gas.

According to this configuration, since H is captured into the film and the captured H is bonded with Si to occupy a bonding hand of Si, the size of the silicon crystal is reduced. As a result, the resistance of the silicide film with gate length of 0.1 micrometers or less can be stabilized.

According to a sixth aspect of the present invention, there is provided a method for manufacturing a semiconductor device, wherein, in the method of the semiconductor device according to the third aspect, the SiH₄ partial pressure is reduced by diluting with rare gas.

According to this configuration, rare gas such as He or Ar can be selected as the gas that flows simultaneously with SiH₄ for reducing the partial pressure of SiH₄, resulting in a small silicon crystal size. According to this configuration, by selecting the rare gas, such as He, Ar or the like as a gas flowing simultaneously with SiH₄, the partial pressure of SiH₄ is reduced, so that the size of the silicon crystal is reduced. As a result, the resistance of the silicide film with gate length of 0.1 micrometers or less can be stabilized.

According to a seventh aspect of the present invention, there is provided a method for manufacturing a semiconductor device, wherein, in the method of the semiconductor device according to the first aspect, the step of depositing the polysilicon film sets a reaction temperature to be in a range of 630° C. to 650° C.

According to this configuration, silicon crystals are grown as columnar crystals having a small size, resulting in a small silicon crystal size. As a result, the resistance of the silicide film with gate length of 0.1 micrometers or less can be stabilized.

According to an eighth aspect of the present invention, there is provided a method for manufacturing a semiconductor device, wherein, in the method of the semiconductor device according to the first aspect, ion implantation is carried out after depositing the polysilicon film.

According to this configuration, when polysilicon or silicon is made amorphous and this amorphous silicon is then recrystallized, ion atoms captured into the film inhibit crystallization, resulting in a small silicon crystal size. As a result, the resistance of the silicide film with gate length of 0.1 micrometers or less can be stabilized.

According to a ninth aspect of the present invention, there is provided a method for manufacturing a semiconductor device, wherein, in the method of the semiconductor device according to the eighth aspect, nitrogen ion implantation is carried out.

According to this configuration, when polysilicon or silicon is made amorphous and this amorphous silicon is then recrystallized, nitrogen captured into the film inhibits crystallization, resulting in a small silicon crystal size.

### BRIEF DESCRIPTION OF THE DRAWINGS

FIG. 1A is a sectional view showing a process of manufacturing a semiconductor device according to an embodiment of the present invention;

FIG. 1B is a sectional view showing the process of manufacturing the semiconductor device according the embodiment of the present invention;

FIG. 1C is a sectional view showing the process of manufacturing the semiconductor device according to the embodiment of the present invention;

FIG. 1D is a sectional view showing the process of manufacturing the semiconductor device according to the embodiment of the present invention;

FIG. 2 is an explanatory view of a SEM image showing a relationship between an SiH₄ partial pressure and a surface morphology;

FIG. 3 is a characteristic chart showing a relationship between the SiH₄ partial pressure and a cobalt silicide resistance;

FIG. 4 is an explanatory view of a SEM image showing a relationship between a film-forming temperature and the surface morphology;

FIG. 5 is a characteristic chart showing a relationship between the film-forming temperature and the cobalt silicide resistance;

FIG. 6A is a sectional view showing a conventional process of manufacturing a semiconductor device;

FIG. 6B is a sectional view showing the conventional process of manufacturing the semiconductor device;

FIG. 6C is a sectional view showing the conventional process of manufacturing the semiconductor device;

FIG. 6D is a sectional view showing the conventional process of manufacturing the semiconductor device; and

FIG. 7 is a schematic diagram schematically showing a crystal structure of a polysilicon film.

### DETAILED DESCRIPTION OF THE PREFERRED EMBODIMENTS

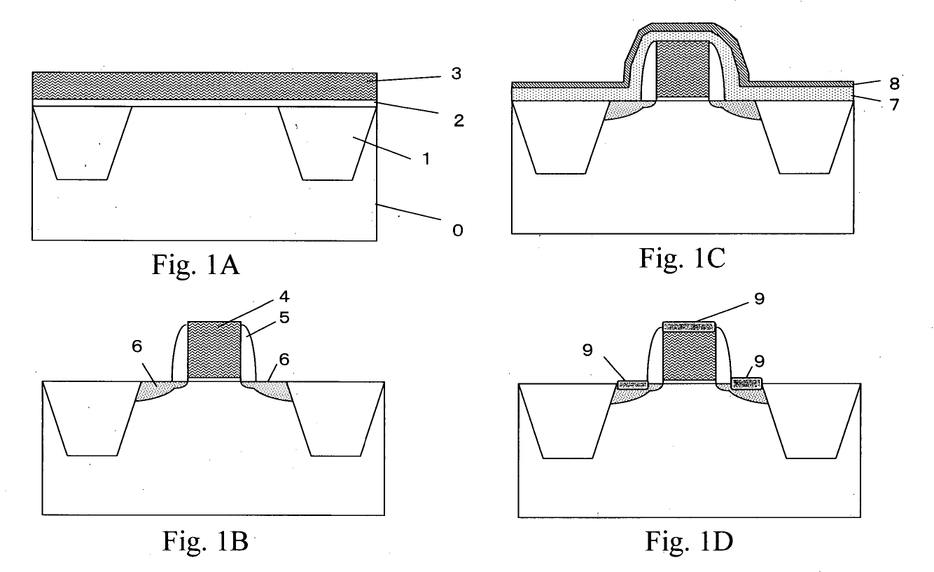

A first embodiment of the present invention will be described based on FIGS. 1 through 3. FIGS. 1A through 1D are sectional views showing a process of manufacturing a semiconductor device according to the first embodiment of the present invention.

First, at a process shown in FIG. 1A, after forming the insulation film for device isolation 1 with a trench shape surrounding an active region on a p-type semiconductor substrate 0, a gate insulation film 2 composed of a silicon oxide film is formed on the active region of the semiconductor substrate 0. Subsequently, a polysilicon film 3 is deposited on the substrate by LPCVD (Low Pressure Chemical Vapor Deposition) at a film-forming temperature of 600° C. to 620° C., a film-forming pressure of 1 Pa to 15 Pa, and an SiH₄ flow-rate of 500 sccm to 1,000 sccm. In this process, the film-forming pressure for polysilicon film growth is set in a range of 1 Pa to 15 Pa, so that the partial pressure of SiH₄ is reduced, resulting in a small silicon crystal size. In this process, in order to set the partial pressure of SiH₄ lower, the pressure is preferably set lower.

Next, at a process shown in FIG. 1B, a gate electrode 4 is formed on the gate insulation film 2 by patterning the polysilicon film using lithography and dry etching. Then, low-concentration impurity ions are implanted into an active region using the gate electrode 4 and the insulation film for device isolation 1 as a mask, so that an LDD region is formed in a self-aligning manner to the gate electrode 4. Then, an oxide film is deposited on the substrate using a CVD method, and a sidewall 5 composed of the oxide film is formed on the side of the gate electrode 4 by etching-back the oxide film. Then, high-concentration impurity ions are implanted into the active region using the gate electrode 4, the sidewall 5 and the insulating film for device isolation 1 as a mask, so that high-concentration source/drain regions 6 are formed therein in a self-aligning manner to the gate electrode 4.

Next, at a process shown in FIG. 1C, by a sputtering method, after a cobalt film 7 is deposited on the substrate, a titanium nitride film 8 is deposited on the cobalt film 7. Next, at a process shown in FIG. 1D, a first short time heat treatment (RTA) is applied to the semiconductor substrate 0 at a temperature of approximately 400° C. to 500° C. in a nitrogen gas atmosphere, and silicon (Si) and cobalt (Co) are reacted in exposed portions of the gate electrode 4 and the high-concentration source/drain regions 6 to form a first cobalt silicide film 9 having cobalt-rich formation. At this time, the cobalt film 7 on the sidewall 5 and on the insulation film, such as the isolation film for device isolation 1 or the like is not silicidized and the cobalt film 7 is left unreacted. Next, by selectively removing the titanium nitride film 8 and the cobalt film 7 that are left unreacted using a solution such as a mixture of sulfuric acid and oxygenated water, the first cobalt silicide film 9 composed of polycrystals is selectively left on the gate electrode 4 and the high-concentration source/drain regions 6.

Next, a second short time heat treatment (RTA) is applied to the semiconductor substrate 0 at a temperature of approximately 800° C. to 900° C. in a nitrogen gas atmosphere, so that the first cobalt silicide film 9 is transformed into a second cobalt silicide film (CoSi₂ film) that is structurally stable (not shown). As a result, a sheet resistance of the second cobalt silicide film is reduced to be lower than that of the first cobalt silicide film 9, thereby making it possible to achieve a reduction in resistance of the gate electrode 4 and the high-concentration source/drain regions 6.

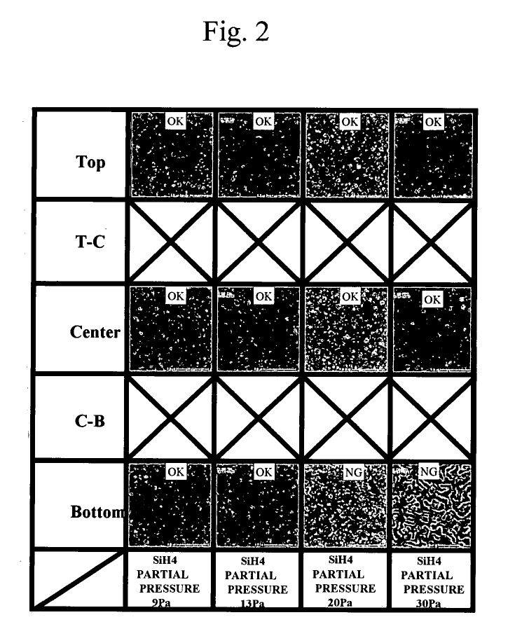

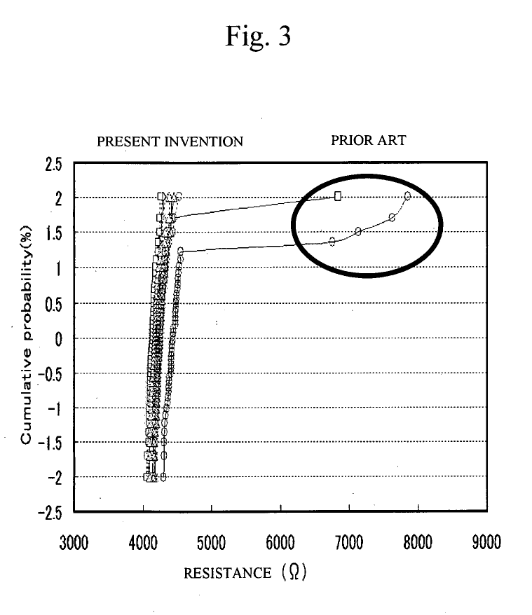

FIG. 2 is an explanatory view of a SEM image showing a surface morphology when an SiH₄ partial pressure is changed, and FIG. 3 is a characteristic chart showing a cobalt silicide resistance when the SiH₄ partial pressure is changed. As shown in FIGS. 2 and 3, when the partial pressure of SiH₄ is reduced, the silicon crystal size is also reduced, so that there will not be found such a problem that the resistance of the silicide film increases because the silicide film is also condensed by an influence of the polysilicon film, thereby the surface morphology is improved. In addition, although the larger the crystal size and the shorter the gate length is, the larger the degree of variance in the number of crystals is, because of reducing the crystal size, the resistance of the silicide film with gate length of 0.1 micrometers or less can be stabilized.

The second embodiment of the present invention will be described next. A process of manufacturing a semiconductor device according to the second embodiment of the present invention will be described using FIGS. 1A through 1D.

First, at the process shown in FIG. 1A, after forming the insulation film for device isolation 1 with a trench shape surrounding an active region on the p-type semiconductor substrate 0, the gate insulation film 2 composed of a silicon oxide film is formed on the active region of the semiconductor substrate 0. Subsequently, the polysilicon film 3 is deposited on the substrate by LPCVD (Low Pressure Chemical Vapor Deposition) at a film-forming temperature of 600° C. to 620° C., a film-forming pressure of 20 Pa to 50 Pa, an SiH₄ flow-rate of 500 sccm to 2,000 sccm, and an N₂ flow-rate of 300 sccm to 3,000 sccm. During this process, by flowing N₂ with a partial pressure between 300 sccm and 3,000 sccm simultaneously at polysilicon film growth, the partial pressure of SiH₄ becomes low causing reduction in size of silicon crystals. At this process, since N₂ gas is made to flow simultaneously to set the partial pressure of SiH₄ low, a desired grain size can be obtained by controlling a ratio of N₂ flow rate and SiH₄ flow rate.

Next, at the process shown in FIG. 1B, the polysilicon film is patterned using lithography and dry etching to form the gate electrode 4 on the gate insulation film 2. Then, low-concentration impurity ions are implanted into an active region using the gate electrode 4 and the insulation film for device isolation 1 as a mask, so that an LDD region is formed in a self-aligning manner to the gate electrode 4. Then, an oxide film is deposited on the substrate using a CVD method, and the sidewall 5 composed of an oxide film is formed on the side of the gate electrode 4 by etching-back the oxide film. Then, high-concentration impurity ions are implanted into the active region using the gate electrode 4, the sidewall 5, and the insulating film for device isolation 1 as a mask, and high-concentration source/drain regions 6 are formed therein in a self-aligning manner to the gate electrode 4.

Next, at the process shown in FIG. 1C, using a sputtering method, after depositing the cobalt film 7 on the substrate, the titanium nitride film 8 is deposited on the cobalt film 7. Next, at the process shown in FIG. 1D, a first short time heat treatment (RTA) is applied to the semiconductor substrate 0 at a temperature of approximately 400° C. to 500° C. in a nitrogen gas atmosphere, and silicon (Si) and cobalt (Co) are reacted in exposed portions of the gate electrode 4 and the high-concentration source/drain regions 6 to form the first cobalt silicide film 9 having cobalt-rich formation. At this time, the cobalt film 7 on the sidewall 5 and on the insulation film, such as the isolation film for device isolation 1 or the like is not silicidized and the cobalt film 7 is left unreacted. Next, by selectively removing the titanium nitride film 8 and the cobalt film 7 that are left unreacted using a solution such as a mixture of sulfuric acid and oxygenated water, the first cobalt silicide film 9 composed of polycrystals is selectively left on the gate electrode 4 and the high-concentration source/drain regions 6.

Next, a second short time heat treatment (RTA) is applied to the semiconductor substrate 0 at a temperature of approximately 800° C. to 900° C. in a nitrogen gas atmosphere, so that the first cobalt silicide film 9 is transformed into a second cobalt silicide film (CoSi₂ film) that is structurally stable (not shown). As a result, a sheet resistance of the second cobalt silicide film is reduced to be lower than that of the first cobalt silicide film 9, thereby making it possible to achieve a reduction in resistance of the gate electrode 4 and the high-concentration source/drain regions 6.

In a manner similar to the first embodiment, FIG. 2 shows a surface morphology when the SiH₄ partial pressure is changed, and FIG. 3 shows a cobalt silicide resistance when the SiH₄ partial pressure is changed. When the partial pressure of SiH₄ is reduced, the silicon crystal size is also reduced, thereby the surface morphology is improved. Moreover, the resistance of the silicide film with gate length of 0.1 micrometers or less can be stabilized.

A third embodiment of the present invention will be described. A process of manufacturing a semiconductor device according to the third embodiment of the present invention will be described using FIGS. 1A through 1D.

First, at the process shown in FIG. 1A, after forming the insulation film for device isolation 1 with a trench shape surrounding an active region on the p-type semiconductor substrate 0, the gate insulation film 2 composed of a silicon oxide film is formed on the active region of the semiconductor substrate 0. Subsequently, the polysilicon film 3 is deposited on the substrate by LPCVD (Low Pressure Chemical Vapor Deposition) at a film-forming temperature of 600° C. to 620° C., a film-forming pressure of 20 Pa to 50 Pa, and an SiH₄ flow-rate of 500 sccm to 2,000 sccm and H₂ flow-rate of 200 sccm to 500 sccm. In this process, H₂ gas of 200 sccm to 500 sccm is made to flow simultaneously during a polysilicon film growth, so that H is captured into the film and the captured H is bonded with Si to occupy a bonding hand of Si, resulting in a small silicon crystal size. In this process, since H₂ gas is made to flow simultaneously to introduce H into the polysilicon film, the bonding hand of Si is occupied, by controlling the ratio of the H₂ flow-rate and the SiH₄ flow-rate, the grain size of crystals can be controlled to a desired value.

Next, at the process shown in FIG. 1B, the polysilicon film is patterned using lithography and dry etching to form the gate electrode 4 on the gate insulation film 2. Then, low-concentration impurity ions are implanted into an active region using the gate electrode 4 and the insulation film for device isolation 1 as a mask, so that an LDD region is formed in a self-aligning manner to the gate electrode 4. Then, an oxide film is deposited on the substrate using a CVD method, and a sidewall 5 composed of the oxide film is formed on the side of the gate electrode 4 by etching-back the oxide film. Then, high-concentration impurity ions are implanted into the active region using the gate electrode 4, the sidewall 5, and the insulating film for device isolation 1 as a mask, and high-concentration source/drain regions 6 are formed therein in a self-aligning manner to the gate electrode 4.

Next, at the process shown in FIG. 1C, using a sputtering method, after depositing the cobalt film 7 on the substrate, the titanium nitride film 8 is deposited on the cobalt film 7. Next, at the process shown in FIG. 1D, a first short time heat treatment (RTA) is applied to the semiconductor substrate 0 at a temperature of approximately 400° C. to 500° C. in a nitrogen gas atmosphere, and silicon (Si) and cobalt (Co) are reacted in exposed portions of the gate electrode 4 and the high-concentration source/drain regions 6 to form the first cobalt silicide film 9 having cobalt-rich formation. At this time, the cobalt film 7 on the sidewall 5 and on the insulation film, such as the isolation film for device isolation 1 or the like is not silicidized and the cobalt film 7 is left unreacted. Next, by selectively removing the titanium nitride film 8 and the cobalt film 7 that are left unreacted using a solution such as a mixture of sulfuric acid and oxygenated water, the first cobalt silicide film 9 composed of polycrystals is selectively left on the gate electrode 4 and the high-concentration source/drain regions 6.

Next, a second short time heat treatment (RTA) is applied to the semiconductor substrate 0 at a temperature of approximately 800° C. to 900° C. in a nitrogen gas atmosphere, so that the first cobalt silicide film 9 is transformed into a second cobalt silicide film (CoSi₂ film) that is structurally stable (not shown). As a result, a sheet resistance of the second cobalt silicide film is reduced to be lower than that of the first cobalt silicide film 9, thereby making it possible to achieve a reduction in resistance of the gate electrode 4 and the high-concentration source/drain regions 6.

In a manner similar to the first embodiment, FIG. 2 shows a surface morphology when the SiH₄ partial pressure is changed, and FIG. 3 shows a cobalt silicide resistance when the SiH₄ partial pressure is changed. When the partial pressure of SiH₄ is reduced, the silicon crystal size is also reduced, thereby the surface morphology is improved. Moreover, the resistance of the silicide film with gate length of 0.1 micrometers or less can be stabilized.

Next, a fourth embodiment of the present invention will be described. A process of manufacturing a semiconductor device according to the fourth embodiment of the present invention will be described using FIGS. 1A through 1D.

First, at the process shown in FIG. 1A, after forming the insulation film for device isolation 1 with a trench shape surrounding an active region on the p-type semiconductor substrate 0, the gate insulation film 2 composed of a silicon oxide film is formed on the active region of the semiconductor substrate 0. Then, the polysilicon film 3 is deposited on the substrate by LPCVD (Low Pressure Chemical Vapor Deposition) using a film-forming temperature of 600° C. to 620° C., a film-forming pressure of 20 Pa to 50 Pa, an SiH₄ flow-rate of 500 sccm to 1,000 sccm and an N₂ flow-rate of 300 sccm to 3,000 sccm. After depositing the polysilicon, implantation of nitrogen ions (N⁺ or N²⁺) is carried out at an acceleration energy of 10 KeV to 50 KeV, and a dose amount of 1×10¹³ to 1×10¹⁵, so that polysilicon or silicon is made amorphous. When recrystallizing this amorphous silicon, N captured into the film inhibits crystallization and the silicon crystal size is reduced. In this process, since the polysilicon film is made amorphous silicone by implantation of nitrogen ions (N⁺ or N²⁺), by controlling an injection rate and an injection energy, it can be controlled into a grain size at the time of recrystallization. Incidentally, argon ions may be used as the implantation ions instead of nitrogen ions.

Next, at the process shown in FIG. 1B, the polysilicon film is patterned using lithography and dry etching to form the gate electrode 4 on the gate insulation film 2. Then, low-concentration impurity ions are implanted into an active region using the gate electrode 4 and the insulation film for device isolation 1 as a mask, so that an LDD region is formed in a self-aligning manner to the gate electrode 4. Then, an oxide film is deposited on the substrate using a CVD method, and the sidewall 5 composed of the oxide film is formed on the side of the gate electrode 4 by etching-back the oxide film. Then, high-concentration impurity ions are implanted into the active region using the gate electrode 4, the sidewall 5 and the insulating film for device isolation 1 as a mask, and a high-concentration source-drain region 6 is formed therein in a self-aligning manner to the gate electrode 4.

Next, at the process shown in FIG. 1C, using a sputtering method, after depositing the cobalt film 7 on the substrate, the titanium nitride film 8 is deposited on the cobalt film 7. Next, at the process shown in FIG. 1D, a first short time heat treatment (RTA) is applied to the semiconductor substrate 0 at a temperature of approximately 400° C. to 500° C. in a nitrogen gas atmosphere, and silicon (Si) and cobalt (Co) are reacted in exposed portions of the gate electrode 4 and the high-concentration source/drain regions 6 to form the first cobalt silicide film 9 having cobalt-rich formation. At this time, the cobalt film 7 on the sidewall 5 and on the insulation film, such as the isolation film for device isolation 1 or the like is not silicidized and the cobalt film 7 is left unreacted. Next, by selectively removing the titanium nitride film 8 and the cobalt film 7 that are left unreacted using a solution such as a mixture of sulfuric acid and oxygenated water, the first cobalt silicide film 9 composed of polycrystals is selectively left on the gate electrode 4 and the high-concentration source/drain regions 6.

Next, a second short time heat treatment (RTA) is applied to the semiconductor substrate 0 at a temperature of approximately 800° C. to 900° C. in a nitrogen gas atmosphere, so that the first cobalt silicide film 9 is transformed into a second cobalt silicide film (CoSi₂ film) that is structurally stable (not shown). As a result, a sheet resistance of the second cobalt silicide film is reduced to be lower than that of the first cobalt silicide film 9, thereby making it possible to achieve a reduction in resistance of the gate electrode 4 and the high-concentration source/drain regions 6.

In a manner similar to the first embodiment, FIG. 2 shows a surface morphology when the SiH₄ partial pressure is changed, and FIG. 3 shows a cobalt silicide resistance when the SiH₄ partial pressure is changed. When the partial pressure of SiH₄ is reduced, the silicon crystal size is also reduced, thereby the surface morphology is improved. Moreover, the resistance of the silicide film with gate length of 0.1 micrometers or less can be stabilized.

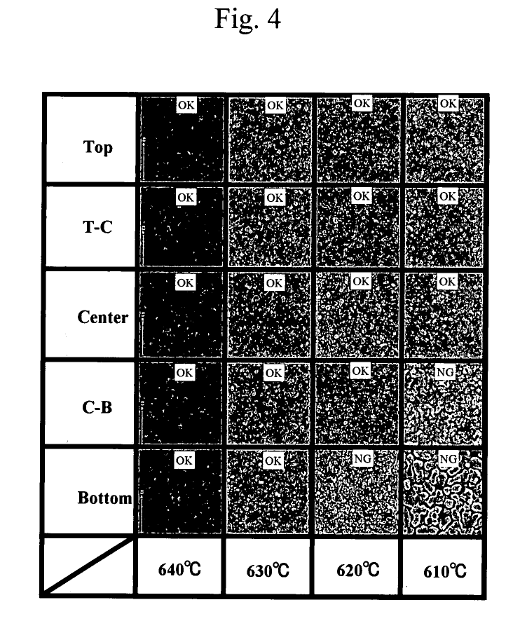

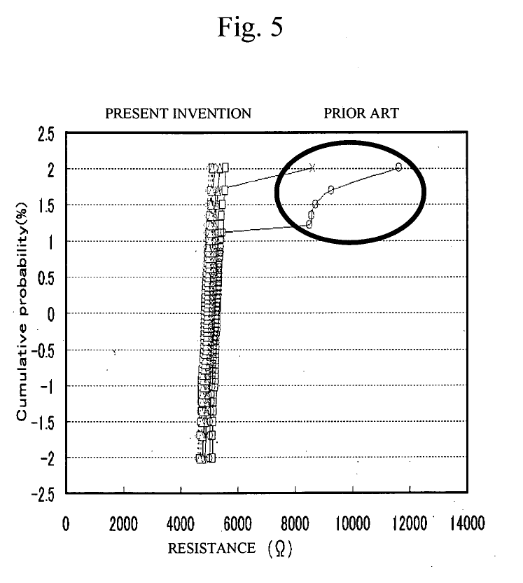

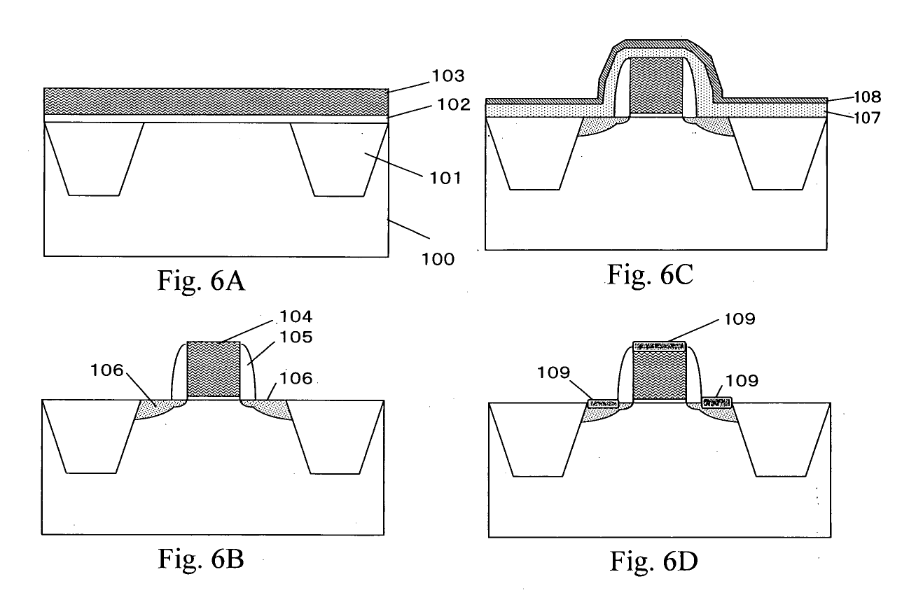

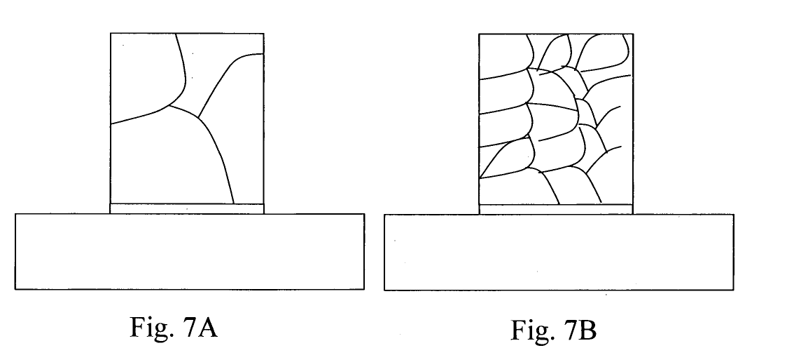

A fifth embodiment of the present invention will be described based on FIGS. 4 and 5. A process of manufacturing a semiconductor device according to the fifth embodiment of the present invention will be described using FIGS. 1A through 1D.

First, at the process shown in FIG. 1A, after forming the insulation film for device isolation 1 with a trench shape surrounding an active region on the p-type semiconductor substrate 0, the gate insulation film 2 composed of a silicon oxide film is formed on the active region of the semiconductor substrate 0. Subsequently, the polysilicon film 3 is deposited on the substrate by LPCVD (Low Pressure Chemical Vapor Deposition) at a film-forming temperature of 630° C. to 650° C., a film-forming pressure of 10 Pa to 20 Pa, and an SiH₄ flow-rate of 500 sccm to 1,000 sccm. In this process, the film-forming temperature of the polysilicon film growth is increased to 630° C. to 650° C., so that silicon crystals are grown as columnar crystals having a small size, resulting in a small silicon crystal size.

Next, at the process shown in FIG. 1B, the polysilicon film is patterned using lithography and dry etching to form the gate electrode 4 on the gate insulation film 2. Then, low-concentration impurity ions are implanted into the active region using the gate electrode 4 and the insulation film for device isolation 1 as a mask, so that an LDD region is formed in a self-aligning manner to the gate electrode 4. Then, an oxide film is deposited on the substrate using a CVD method, and the sidewall 5 composed of the oxide film is formed on the side of the gate electrode 4 by etching-back the oxide film. Then, high-concentration impurity ions are implanted into the active region using the gate electrode 4, the sidewall 5 and the insulating film for device isolation 1 as a mask, so that high-concentration source/drain regions 6 are formed therein in a self-aligning manner to the gate electrode 4.

Next, at the process shown in FIG. 1C, using a sputtering method, after depositing the cobalt film 7 on the substrate, the titanium nitride film 8 is deposited on the cobalt film 7. Next, at the process shown in FIG. 1D, a first short time heat treatment (RTA) is applied to the semiconductor substrate 0 at a temperature of approximately 400° C. to 500° C. in a nitrogen gas atmosphere, and silicon (Si) and cobalt (Co) are reacted in exposed portions of the gate electrode 4 and the high-concentration source/drain regions 6 to form the first cobalt silicide film 9 having cobalt-rich formation. At this time, the cobalt film 7 on the sidewall 5 and on the insulation film, such as the isolation film for device isolation 1 or the like is not silicidized and the cobalt film 7 is left unreacted. Next, by selectively removing the titanium nitride film 8 and the cobalt film 7 that are left unreacted using a solution such as a mixture of sulfuric acid and oxygenated water, the first cobalt silicide film 9 composed of polycrystals is selectively left on the gate electrode 4 and the high-concentration source/drain regions 6.

Next, a second short time heat treatment (RTA) is applied to the semiconductor substrate 0 at a temperature of approximately 800° C. to 900° C. in a nitrogen gas atmosphere, so that the first cobalt silicide film 9 is transformed into a second cobalt silicide film (CoSi₂ film) that is structurally stable (not shown). As a result, a sheet resistance of the second cobalt silicide film is reduced to be lower than that of the first cobalt silicide film 9, thereby making it possible to achieve a reduction in resistance of the gate electrode 4 and the high-concentration source/drain regions 6.

FIG. 4 is an explanatory view of the SEM image showing the surface morphology when the film-forming temperature is changed, and FIG. 5 is a characteristic chart showing the cobalt silicide resistance when the film-forming temperature is changed. As shown in FIGS. 4 and 5, when the film-forming temperature increased, the silicon crystal size is reduced, so that there will not be found such a problem that the resistance of the silicide film increases because the silicide film is also condensed by an influence of the polysilicon film, thereby the surface morphology is improved. Moreover, although the larger the crystal size and the shorter the gate length is, the larger the degree of variance in the number of crystals is, because of reducing the crystal size, the resistance of the silicide film with gate length of 0.1 micrometers or less can be stabilized.

1. A method for manufacturing a semiconductor device, comprising the steps of:
forming a gate insulation film on a silicon substrate to deposit a polysilicon film on said gate insulation film; and
patterning the polysilicon film to form a gate electrode on the gate insulation film,
wherein said gate electrode is silicidized to form a silicide film, and
by reducing a crystal size in said polysilicon film and reducing a degree of variance of the number of crystals contained in said polysilicon film, a resistance of said silicide film is stabilized.

2. The method for manufacturing the semiconductor device according to claim 1, wherein said step of depositing the polysilicon film sets a reaction pressure to be in a range of 1 Pa to 15 Pa.

3. The method for manufacturing the semiconductor device according to claim 1, wherein said step of depositing the polysilicon film sets an SiH₄ partial pressure to be in a range of 1 Pa to 15 Pa.

4. The method for manufacturing the semiconductor device according to claim 3, wherein the SiH₄ partial pressure is reduced by diluting with N₂ gas.

5. The method for manufacturing the semiconductor device according to claim 3, wherein the SiH₄ partial pressure is reduced by diluting with H₂ gas.

6. The method for manufacturing the semiconductor device according to claim 3, wherein the SiH₄ partial pressure is reduced by diluting with rare gas.

7. The method for manufacturing the semiconductor device according to claim 1, wherein the step of depositing the polysilicon film sets a reaction temperature to be in a range of 630° C. to 650° C.

8. The method for manufacturing the semiconductor device according to claim 1, wherein ion implantation is carried out after depositing the polysilicon film.

9. The method for manufacturing the semiconductor device according to claim 8, wherein nitrogen ion implantation is carried out.
